(19) United States
(12) Patent Application Publication
(10) Pub. No.: US 2025/0234612 A1
(43) Pub. Date: Jul. 17, 2025

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Dong Gun Kim, Suwon-si (KR); Jung-Hwan Kim, Suwon-si (KR); Hee Chan Song, Suwon-si (KR); Chun Hyung Chung, Suwon-si (KR)

(21) Appl. No.: 18/767,177

(22) Filed: Jul. 9, 2024

(30) Foreign Application Priority Data
Jan. 11, 2024 (KR) 10-2024-0004807

(51) Int. Cl. H01L 29/20; H01L 21/768; H01L 27/092; H01L 29/10; H01L 29/205; H01L 29/423; H01L 29/66; H01L 29/786

(52) U.S. Cl. CPC H10D 62/8503; H01L 21/76801; H01L 21/76838; H10D 30/031; H10D 30/6755; H10D 30/751; H10D 62/824; H10D 64/512; H10D 84/85

(57) ABSTRACT

An example semiconductor device includes a substrate comprising an NMOS region and a PMOS region, a first gate insulating layer disposed on an upper surface of the substrate in the NMOS region, a first NMOS conductive layer contacting an upper surface of the first gate insulating layer and comprising lanthanum oxide (LaO), a second NMOS conductive layer contacting an upper surface of the first NMOS conductive layer, a second gate insulating layer disposed on the upper surface of the substrate in the PMOS region, a first PMOS conductive layer disposed on an upper surface of the second gate insulating layer, a second PMOS conductive layer disposed on an upper surface of the first PMOS conductive layer, and an oxynitride layer disposed between the first PMOS conductive layer and the second PMOS conductive layer. The oxynitride layer contacts the first PMOS conductive layer and the second PMOS conductive layer.

### CROSS-REFERENCE TO RELATED APPLICATION

This application claims priority from Korean Patent Application No. 10-2024-0004807 filed on Jan. 11, 2024 in the Korean Intellectual Property Office, and all the benefits accruing therefrom under 35 U.S.C. 119, the contents of which in its entirety are herein incorporated by reference.

### BACKGROUND

As the feature size of MOS transistors is reduced, the length of the gate and the length of the channel formed below it also becomes smaller. Accordingly, several works have been conducted to increase the capacitance between the gate and the channel and improve the operational characteristics of MOS transistors.

In addition, conventionally, the process difficulty of forming NMOS transistors and PMOS transistors has increased due to an increase in the step difference between NMOS transistors and PMOS transistors. Accordingly, research is being conducted to reduce the process difficulty by reducing the step difference between NMOS transistors and PMOS transistors.

### SUMMARY

The present disclosure relates to a semiconductor device and a method of fabricating the semiconductor device that reduce the step difference between the gate structures of the PMOS region and the NMOS region, thereby reducing the process complexity.

The aspects of the present disclosure are not limited to those mentioned above and another aspect which is not mentioned may be clearly understood by those skilled in the art from the description below.

In general, according to some aspects, a semiconductor device comprises a substrate comprising an NMOS region and a PMOS region, a first gate insulating layer disposed on an upper surface of the substrate in the NMOS region, a first NMOS conductive layer being in contact with an upper surface of the first gate insulating layer and comprising lanthanum oxide (LaO), a second NMOS conductive layer being in contact with an upper surface of the first NMOS conductive layer, a second gate insulating layer disposed on the upper surface of the substrate in the PMOS region, a first PMOS conductive layer disposed on an upper surface of the second gate insulating layer, a second PMOS conductive layer disposed on an upper surface of the first PMOS conductive layer, and an oxynitride layer disposed between the first PMOS conductive layer and the second PMOS conductive layer, the oxynitride layer being in contact with each of the first PMOS conductive layer and the second PMOS conductive layer, wherein each of the second NMOS conductive layer, the first PMOS conductive layer and the second PMOS conductive layer comprises the same material, and wherein a thickness of the second PMOS conductive layer in a vertical direction is the same as a thickness of the second NMOS conductive layer in the vertical direction.

In general, according to some aspects, a method of fabricating a semiconductor device comprises providing a substrate comprising an NMOS region and a PMOS region, forming a first gate insulating layer on an upper surface of the substrate in the NMOS region, and forming a second gate insulating layer on the upper surface of the substrate in the PMOS region, forming a first PMOS conductive layer on an upper surface of the second gate insulating layer, forming a protective layer being in contact with an upper surface of the first PMOS conductive layer, forming a first NMOS conductive layer being in contact with an upper surface of the first gate insulating layer, the first NMOS conductive layer comprising lanthanum oxide (LaO), removing the protective layer, forming an oxynitride layer being in contact with the upper surface of the first PMOS conductive layer, and forming a second NMOS conductive layer being in contact with an upper surface of the first NMOS conductive layer, and forming a second PMOS conductive layer being in contact with an upper surface of the oxynitride layer, wherein each of the second NMOS conductive layer, the first PMOS conductive layer and the second PMOS conductive layer comprises the same material.

In general, according to some aspects, a method of fabricating a semiconductor device comprises providing a substrate comprising an NMOS region and a PMOS region, forming a silicon-germanium layer being in contact with an upper surface of the substrate of the PMOS region, the silicon-germanium layer comprising silicon germanium (SiGe), forming a first gate insulating layer on the upper surface of the substrate in the NMOS region, and forming a second gate insulating layer on an upper surface of the silicon-germanium layer in the PMOS region, forming a first PMOS conductive layer on an upper surface of the first gate insulating layer and an upper surface of the second gate insulating layer, respectively, removing the first PMOS conductive layer formed on the upper surface of the first gate insulating layer, forming a protective layer being in contact with an upper surface of the first PMOS conductive layer, the protective layer comprising Aniline, forming a first NMOS conductive layer being in contact with the upper surface of the first gate insulating layer, the first NMOS conductive layer comprising lanthanum oxide (LaO), removing the protective layer, forming an oxynitride layer being in contact with the upper surface of the first PMOS conductive layer, the oxynitride layer comprising titanium oxynitride (TiON), and forming a second NMOS conductive layer being in contact with an upper surface of the first NMOS conductive layer, and forming a second PMOS conductive layer being in contact with an upper surface of the oxynitride layer, wherein each of the second NMOS conductive layer, the first PMOS conductive layer and the second PMOS conductive layer comprises titanium nitride (TiN), and wherein a thickness of the second PMOS conductive layer in a vertical direction is the same as a thickness of the second NMOS conductive layer in the vertical direction.

### BRIEF DESCRIPTION OF THE DRAWINGS

The above and other aspects and features of the present disclosure will become more apparent by describing in detail exemplary implementations thereof with reference to the attached drawings.

FIG. 1 is a diagram for explaining an example of a semiconductor device.

FIGS. 2 to 12 are intermediate diagrams for explaining an example of a method of fabricating a semiconductor device.

FIG. 13 is a diagram for explaining an example of a semiconductor device.

FIGS. 14 and 15 are intermediate diagrams for explaining an example of a method of fabricating the semiconductor device.

FIG. 16 is a diagram for explaining an example of a semiconductor device.

FIGS. 17 and 18 are intermediate diagrams for explaining an example of a method of fabricating the semiconductor device.

FIG. 19 is a schematic layout of an example of a semiconductor device.

FIG. 20 is an example schematic layout view of an enlarged portion of R3 of FIG. 19.

FIG. 21 is an example cross-sectional view taken along line A-A of FIG. 20.

FIG. 22 is an example cross-sectional view taken along line B-B of FIG. 20.

FIG. 23 is a layout diagram for explaining an example of a semiconductor device.

FIG. 24 is a perspective view for explaining an example of a semiconductor device.

FIG. 25 is an example cross-sectional view taken along each of the lines C-C and D-D in FIG. 23.

FIG. 26 is a layout diagram for explaining an example of a semiconductor device.

FIG. 27 is a perspective view for explaining an example of a semiconductor device.

### DETAILED DESCRIPTION

In the following diagram of a semiconductor device according to some implementations, it is exemplarily described that the semiconductor device comprises planar transistors. However, the present disclosure is not limited thereto. In some implementations, the semiconductor device may comprise a fin-type transistor (FinFET) with a channel region in a fin-type pattern, a transistor comprising nanosheets (MBCFETTM—Multi-Bridge Channel Field Effect Transistor), or a three-dimensional (3D) transistor.

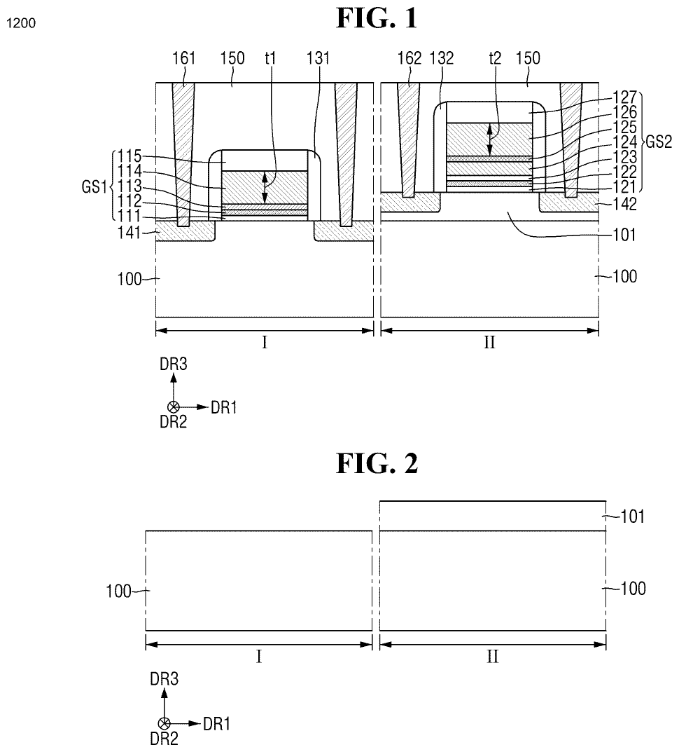

Hereinafter, the semiconductor device according to some implementations of the present disclosure will be described with reference to FIG. 1.

FIG. 1 is a diagram for explaining an example of the semiconductor device.

Referring to FIG. 1, the semiconductor device according to some implementations of the present disclosure comprises a substrate 100, a silicon-germanium layer 101, a first gate structure GS1, a second gate structure GS2, a first gate spacer 131, a second gate spacer 132, a first source/drain region 141, a second source/drain region 142, an interlayer insulating layer 150, a first source/drain contact 161, and a second source/drain contact 162.

The substrate 100 may be a silicon substrate or silicon-on-insulator (SOI). Alternatively, the substrate 100 may comprise silicon germanium, silicon germanium on insulator (SGOI), indium antimonide, lead telluride, indium arsenide, indium phosphide, gallium arsenide, or gallium antimonide, however, the present disclosure is not limited thereto. In some implementations, the substrate 100 may take the form of a silicon substrate bonded to a base substrate made of a different material. For example, the base substrate may be a substrate made of a compound semiconductor as described above, but the present disclosure is not limited thereto.

For example, the substrate 100 may comprise an NMOS region I and a PMOS region II.

For example, the NMOS region I may be a region in which NMOS transistors are formed, and the PMOS region II may be a region in which PMOS transistors are formed. That is, NMOS transistors may be formed on the substrate 100 in the NMOS region I, and PMOS transistors may be formed on the substrate 100 in the PMOS region II. For example, the upper surface of the substrate 100 in the NMOS region I and the upper surface of the substrate 100 in the PMOS region II may be formed on the same plane.

Hereinafter, each of a first horizontal direction DR1 and a second horizontal direction DR2 may be defined as a direction parallel to the upper surface of the substrate 100. The second horizontal direction DR2 may be defined as a direction perpendicular to the first horizontal direction DR1. The vertical direction DR3 may be defined as the direction perpendicular to each of the first horizontal direction DR1 and the second horizontal direction DR2, that is, the vertical direction DR3 may be defined as a direction perpendicular to the upper surface of the substrate 100.

The silicon-germanium layer 101 may be disposed on the upper surface of the substrate 100 in the PMOS region I. For example, the silicon-germanium layer 101 may be in contact with the upper surface of the substrate 100 in the PMOS region II. For example, the silicon-germanium layer 101 is not disposed on the upper surface of the substrate 100 in the NMOS region I. For example, the upper surface of the silicon-germanium layer 101 may be higher than the upper surface of the substrate 100 of the NMOS region I. For example, the silicon-germanium layer 101 may comprise silicon germanium (SiGe).

The first gate structure GS1 may be disposed on the upper surface of the substrate 100 in the NMOS region I. For example, the first gate structure GS1 may extend in the second horizontal direction DR2. The first gate structure GS1 may comprise a first interface layer 111, a first gate insulating layer 112, a first NMOS conductive layer 113, a second NMOS conductive layer 114, and a first capping layer 115 stacked sequentially in a vertical direction DR3 on the upper surface of the substrate 100 of the NMOS region I. For instance, the sidewalls of each of the first interface layer 111, the first gate insulating layer 112, the first NMOS conductive layer 113, the second NMOS conductive layer 114, and the first capping layer 115 in a first horizontal direction DR1 may be aligned in a vertical direction DR3.

The second gate structure GS2 may be disposed on an upper surface of the substrate 100 of the PMOS region II. Specifically, the second gate structure GS2 may be disposed on an upper surface of the silicon-germanium layer 101. For example, the second gate structure GS2 may extend in the second horizontal direction DR2. The second gate structure GS2 may comprise a second interface layer 121, a second gate insulating layer 122, a dielectric layer 123, a first PMOS conductive layer 124, an oxynitride layer 125, a second PMOS conductive layer 126, and a second capping layer 127 stacked sequentially in a vertical direction DR3 on the upper surface of the silicon-germanium layer 101. For example, the sidewalls of each of the second interface layer 121, the second gate insulating layer 122, the dielectric layer 123, the first PMOS conductive layer 124, the oxynitride layer 125, the second PMOS conductive layer 126, and the second capping layer 127 in a first horizontal direction DR1 may be aligned in a vertical direction DR3. For example, the upper surface of the second gate structure GS2 may be formed higher than the upper surface of the first gate structure GS1.

The first interface layer 111 may be in contact with the upper surface of the substrate 100 in the NMOS region I. The second interface layer 121 may be in contact with the upper surface of the silicon-germanium layer 101. For example, each of the first interface layer 111 and the second interface layer 121 may comprise silicon oxide (SiO2). The first gate insulating layer 112 may be disposed on the upper surface of the first interface layer 111. The first gate insulating layer 112 may be in contact with the upper surface of the first interface layer 111. The second gate insulating layer 122 may be disposed on the upper surface of the second interface layer 121. The second gate insulating layer 122 may be in contact with the upper surface of the second interface layer 121.

Each of the first gate insulating layer 112 and the second gate insulating layer 122 may comprise at least one of silicon oxide, silicon oxynitride, silicon nitride, or a high-k material having a dielectric constant greater than silicon oxide. The high-k materials may comprise, for example, one or more of hafnium oxide, hafnium silicon oxide, hafnium aluminum oxide, and lanthanum oxide, lanthanum aluminum oxide, zirconium oxide, zirconium silicon oxide, tantalum oxide, titanium oxide, and titanium oxide, barium strontium titanium oxide, barium titanium oxide, strontium titanium oxide, yttrium oxide, aluminum oxide, lead scandium tantalum oxide, or lead zinc niobate.

The semiconductor device according to some implementations may comprise a NC (Negative Capacitance) FET using a negative capacitor. For example, each of the first gate insulating layer 112 and the second gate insulating layer 122 may comprise a ferroelectric material layer having ferroelectric properties and a paraelectric material layer having paraelectric properties.

The ferroelectric material layer may have a negative capacitance, and the paraelectric material layer may have a positive capacitance. For example, if two or more capacitors are connected in series and each capacitor has a positive capacitance, the total capacitance will be decreased than the capacitance of each individual capacitor. On the other hand, if at least one of the capacitances of two or more capacitors connected in series has a negative value, the total capacitance may have a positive value and be greater than the absolute value of each individual capacitance.

When the ferroelectric material layer having a negative capacitance and the paraelectric material layer having a positive capacitance are connected in series, the total capacitance value of the ferroelectric material layer and the paraelectric material layer connected in series may be increased. By using the increase in the overall capacitance value, the transistor comprising the ferroelectric material layer may have a subthreshold swing SS of less than 60 mV/decade at room temperature.

The ferroelectric material layer may have ferroelectric properties. The ferroelectric material layer may comprise, for example, at least one of hafnium oxide, hafnium zirconium oxide, barium strontium titanium oxide, barium titanium oxide, and lead zirconium oxide. Here, as an example, hafnium zirconium oxide may be a material in which zirconium (Zr) is doped into hafnium oxide. As another example, hafnium zirconium oxide may be a compound of hafnium (Hf), zirconium (Zr), and oxygen (O).

The ferroelectric material layer may further comprise a doped dopant. For example, the dopant may comprise at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer comprises, the type of dopant comprised in the ferroelectric material layer may vary.

When the ferroelectric material layer comprises hafnium oxide, the dopant comprised in the ferroelectric material layer may comprise, for example, at least one of gadolinium (Gd), silicon (Si), zirconium (Zr), aluminum (Al), and yttrium (Y).

When the dopant is aluminum Al, the ferroelectric material layer may comprise 3 to 8 at % (atomic %) of aluminum. Here, the ratio of the dopant may be the ratio of aluminum to the sum of hafnium and aluminum.

When the dopant is silicon (Si), the ferroelectric material layer may comprise 2 to 10 at % of silicon. When the dopant is yttrium (Y), the ferroelectric material layer may comprise 2 to 10 at % of yttrium. When the dopant is gadolinium (Gd), the ferroelectric material layer may comprise 1 to 7 at % of gadolinium. When the dopant is zirconium (Zr), the ferroelectric material layer may comprise 50 to 80 at % of zirconium.

The paraelectric material layer may have paraelectric properties. The paraelectric material layer may comprise, for example, at least one of silicon oxide and a metal oxide having a high dielectric constant. The metal oxide comprised in the paraelectric material layer may comprise, for example, at least one of hafnium oxide, zirconium oxide, and aluminum oxide, but is not limited thereto.

The ferroelectric material layer and the paraelectric material layer may comprise the same material. The ferroelectric material layer may have ferroelectric properties, but the paraelectric material layer may not have ferroelectric properties. For example, when the ferroelectric material layer and the paraelectric material layer comprise hafnium oxide, the crystal structure of hafnium oxide comprised in the ferroelectric material layer is different from the crystal structure of hafnium oxide comprised in the paraelectric material layer.

The ferroelectric material layer may have a thickness having ferroelectric properties. The thickness of the ferroelectric material layer may be, for example, 0.5 to 10 nm, but is not limited thereto. Since the critical thickness representing the ferroelectric properties may vary for each ferroelectric material, the thickness of the ferroelectric material layer may vary depending on the ferroelectric material.

As an example, each of the first gate insulating layer 112 and the second gate insulating layer 122 may comprise one ferroelectric material layer. In another example, each of the first gate insulating layer 112 and the second gate insulating layer 122 may comprise a plurality of ferroelectric material layers spaced apart from each other. Each of the first gate insulating layer 112 and the second gate insulating layer 122 may have a laminated layer structure in which the plurality of ferroelectric material layers and the plurality of dielectric material layers are alternately stacked.

The first NMOS conductive layer 113 may be disposed on the upper surface of the first gate insulating layer 112. For example, the first NMOS conductive layer 113 may be in contact with the upper surface of the first gate insulating layer 112. For example, the first NMOS conductive layer 113 may be formed conformally. For example, the first NMOS conductive layer 113 may comprise lanthanum oxide (LaO). In some implementations, the first NMOS conductive layer 113 may comprise lanthanum oxynitride (Loan), scandium oxide (ScO), or scandium oxynitride (ScON).

The second NMOS conductive layer 114 may be disposed on the upper surface of the first NMOS conductive layer 113. For example, the second NMOS conductive layer 114 may be in contact with the upper surface of the first NMOS conductive layer 113. For example, the second NMOS conductive layer 114 may be conformally formed. For example, the second NMOS conductive layer 114 may comprise a metal nitride. For example, the second NMOS conductive layer 114 may comprise titanium nitride (TiN). In some implementations, the second NMOS conductive layer 114 may comprise aluminum nitride (AlN) or titanium aluminum nitride (TiAlN).

The first PMOS conductive layer 124 may be disposed on the upper surface of the second gate insulating layer 122. For example, the first PMOS conductive layer 124 may be spaced apart from the upper surface of the second gate insulating layer 122 in the vertical direction DR3. For example, the first PMOS conductive layer 124 may be formed conformally. For example, the first PMOS conductive layer 124 may comprise a metal nitride. For example, the first PMOS conductive layer 124 may comprise the same material as the second NMOS conductive layer 114. For example, the first PMOS conductive layer 124 may comprise titanium nitride (TiN). In some implementations, the first PMOS conductive layer 124 may comprise aluminum nitride (AlN) or titanium aluminum nitride (TiAlN).

The dielectric layer 123 may be disposed between the upper surface of the second gate insulating layer 122 and the lower surface of the first PMOS conductive layer 124. For example, the dielectric layer 123 may be in contact with the upper surface of the second gate insulating layer 122 and the lower surface of the first PMOS conductive layer 124, respectively. For example, the dielectric layer 123 may be formed conformally. For example, the dielectric layer 123 may comprise aluminum oxide (AlO). In some implementations, the dielectric layer 123 may comprise aluminum oxynitride (AlON), hafnium oxide (HfO), hafnium silicon oxide (HfSiO), or hafnium zirconium oxide (0HfZrO).

The second PMOS conductive layer 126 may be disposed on the upper surface of the first PMOS conductive layer 124. For example, the second PMOS conductive layer 126 may be spaced apart from the upper surface of the first PMOS conductive layer 124 in the vertical direction DR3. For example, the second PMOS conductive layer 126 may be formed conformally. For example, the second PMOS conductive layer 126 may comprise a metal nitride. For example, the second PMOS conductive layer 126 may comprise the same material as each of the second NMOS conductive layer 114 and the first PMOS conductive layer 124. For example, the second PMOS conductive layer 126 may comprise titanium nitride (TiN). In some implementations, the second PMOS conductive layer 126 may comprise aluminum nitride (AlN) or titanium aluminum nitride (TiAlN).

For example, the upper surface of the second PMOS conductive layer 126 may be formed higher than the upper surface of the second NMOS conductive layer 114. For example, the thickness t2 of the second PMOS conductive layer 126 in the vertical direction DR3 may be the same as the thickness t1 of the second NMOS conductive layer 114 in the vertical direction. DR3. For example, the second PMOS conductive layer 126 and the second NMOS conductive layer 114 may be formed through the same fabricating process. A detailed description of this will be provided later.

The oxynitride layer 125 may be disposed between the upper surface of the first PMOS conductive layer 124 and the lower surface of the second PMOS conductive layer 126. For example, the oxynitride layer 125 may be in contact with the upper surface of the first PMOS conductive layer 124 and the lower surface of the second PMOS conductive layer 126, respectively. For example, the oxynitride layer 125 may be formed conformally. For example, the oxynitride layer 125 may comprise a metal oxynitride. For example, the oxynitride layer 125 may comprise titanium oxynitride (TiON). In some implementations, the oxynitride layer 125 may comprise aluminum nitride (AlON) or titanium aluminum nitride (TiAlON).

The first capping layer 115 may be disposed on the upper surface of the second NMOS conductive layer 114. The first capping layer 115 may be in contact with the upper surface of the second NMOS conductive layer 114. The second capping layer 127 may be disposed on the upper surface of the second PMOS conductive layer 126. The second capping layer 127 may be in contact with the upper surface of the second PMOS conductive layer 126. For example, each of the first capping layer 115 and the second capping layer 127 may comprise at least one of silicon nitride (SiN), silicon oxynitride (SiON), silicon oxide SiO2, silicon carbonitride (SiCN), silicon oxycarbonitride (SiOCN), and combinations thereof. However, the present disclosure is not limited thereto. For example, the upper surface of the second capping layer 127 may be formed higher than the upper surface of the first capping layer 115.

The first gate spacer 131 may be disposed on the upper surface of the substrate 100 in the NMOS region I. The first gate spacer 131 may be disposed on both sidewalls of the first gate structure GS1 in the first horizontal direction DR1. For example, the first gate spacer 131 may be in contact with the sidewalls in the first horizontal direction DR1 of the first interface layer 111, the first gate insulating layer 112, the first NMOS conductive layer 113, the second NMOS conductive layer 114, and the first capping layer 115, respectively. For example, the upper surface of the first gate spacer 131 may be formed on the same plane as the upper surface of the first capping layer 115.

The second gate spacer 132 may be disposed on the upper surface of the substrate 100 in the PMOS region II. Specifically, the second gate spacer 132 may be disposed on the upper surface of the silicon-germanium layer 101. The second gate spacer 132 may be disposed on both sidewalls of the second gate structure GS2 in the first horizontal direction DR1. For example, the second gate spacer 132 may be in contact with the sidewalls in the first horizontal direction DR1 of the second interface layer 121, the second gate insulating layer 122, the dielectric layer 123, the first PMOS conductive layer 124, the oxynitride layer 125, the second PMOS conductive layer 126, and the second capping layer 127, respectively. For example, the upper surface of the second gate spacer 132 may be formed on the same plane as the upper surface of the second capping layer 127.

For example, each of the first gate spacer 131 and the second gate spacer 132 may comprise at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and combinations thereof. However, the present disclosure is not limited thereto.

The first source/drain region 141 may be disposed on both sides of the first gate structure GS1 in the first horizontal direction DR1. The first source/drain region 141 may be disposed inside the substrate 100 in the NMOS region I. The second source/drain region 142 may be disposed on both sides of the second gate structure GS2 in the first horizontal direction DR1. The second source/drain region 142 may be disposed inside the silicon-germanium layer 101 of the PMOS region II.

The interlayer insulating layer 150 may be disposed on the upper surface of the substrate 100 in the NMOS region I. The interlayer insulating layer 150 may cover the upper surface of the first source/drain region 141, the sidewalls and upper surface of the first gate spacer 131, and the upper surface of the first capping layer 115, respectively, on the upper surface of the substrate 100 in the NMOS region I. Furthermore, the interlayer insulating layer 150 may be disposed on the upper surface of the silicon-germanium layer 101 in the PMOS region II. The interlayer insulating layer 150 may cover the upper surface of the second source/drain region 142, the sidewalls and upper surface of the second gate spacer 132, and the upper surface of the second capping layer 127, respectively, on the upper surface of the silicon-germanium layer 101 in the PMOS region II.

For example, the interlayer insulating layer 150 may comprise at least one of silicon oxide, silicon nitride, silicon oxynitride, and low-k material. The low-k material may comprise, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica, or combinations thereof, but the present disclosure is not limited thereto.

The first source/drain contact 161 may be connected to the first source/drain region 141 by penetrating the interlayer insulating layer 150 in the vertical direction DR3 on the upper surface of the substrate 100 in the NMOS region I. The second source/drain contact 162 may be connected to the second source/drain region 142 by penetrating the interlayer insulating layer 150 in the vertical direction DR3 on the upper surface of the substrate 100 in the PMOS region II. Each of the first source/drain contact 161 and the second source/drain contact 162 may comprise a conductive material.

Hereinafter, the method of fabricating the semiconductor device according to some implementations of the present disclosure will be described with reference to FIGS. 1 to 12.

FIGS. 2 to 12 are intermediate step diagrams for explaining an example of the method of fabricating the semiconductor device.

Referring to FIG. 2, the substrate 100 comprising the NMOS region I and the PMOS region II may be provided. Subsequently, the silicon-germanium layer 101 may be formed on the upper surface of the substrate 100 in the PMOS region II. For example, the silicon-germanium layer 101 may be in contact with the upper surface of the substrate 100 in the PMOS region II. For example, the silicon-germanium layer 101 is not formed on the upper surface of the substrate 100 in the NMOS region I. For example, the upper surface of the silicon-germanium layer 101 may be formed higher than the upper surface of the substrate 100 in the NMOS region I.

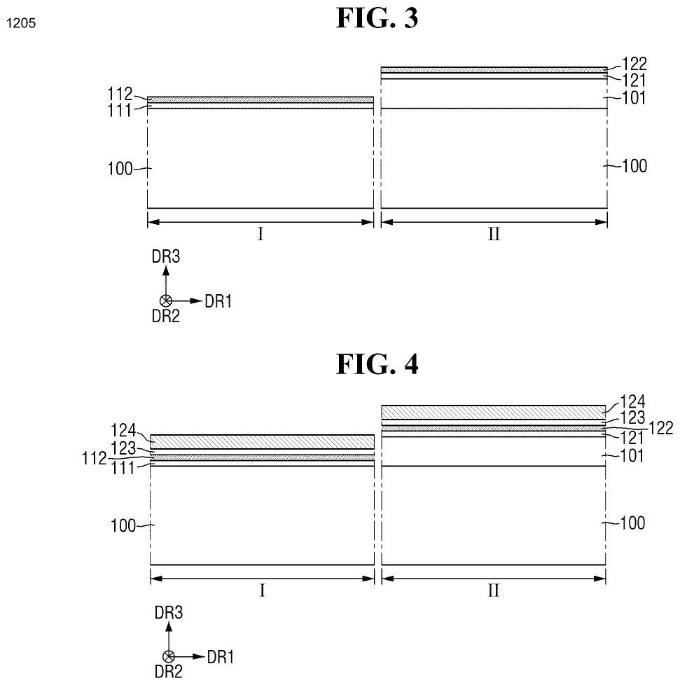

Referring to FIG. 3, the first interface layer 111 and the first gate insulating layer 112 may be formed sequentially on the upper surface of the substrate 100 in the NMOS region I. For example, the first interface layer 111 may be in contact with the upper surface of the substrate 100 in the NMOS region I. The first gate insulating layer 112 may be in contact with the upper surface of the first interface layer 111.

Additionally, the second interface layer 121 and the second gate insulating layer 122 may be formed sequentially on the upper surface of the silicon-germanium layer 101 in the PMOS region II. For example, the second interface layer 121 may be in contact with the upper surface of the silicon-germanium layer 101. The second gate insulating layer 122 may be in contact with the upper surface of the second interface layer 121. For example, the first interface layer 111 and the second interface layer 121 may be formed through the same fabricating process. Also, the first gate insulating layer 112 and the second gate insulating layer 122 may be formed through the same fabricating process.

Referring to FIG. 4, the dielectric layer 123 and the first PMOS conductive layer 124 may be formed sequentially on the upper surface of the first gate insulating layer 112 and the upper surface of the second gate insulating layer 122, respectively. For example, the dielectric layer 123 may be in contact with the upper surface of the first gate insulating layer 112 and an upper surface of the second gate insulating layer 122, respectively. The first PMOS conductive layer 124 may be in contact with the upper surface of the dielectric layer 123.

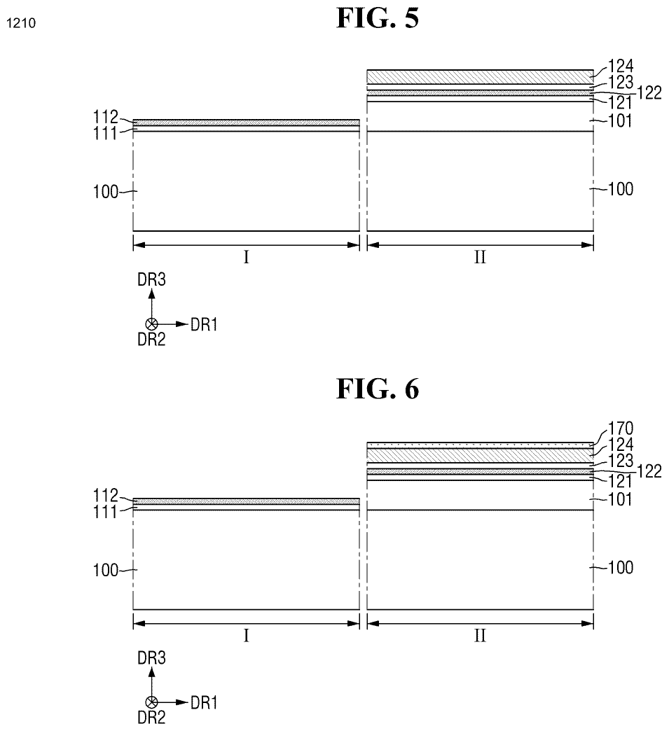

Referring to FIG. 5, the dielectric layer 123 and the first PMOS conductive layer 124 formed on the upper surface of the first gate insulating layer 112 may be removed. That is, the dielectric layer 123 and the first PMOS conductive layer 124 formed on the upper surface of the second gate insulating layer 122 are not removed.

Referring to FIG. 6, a protective layer 170 may be formed on the upper surface of the first PMOS conductive layer 124. For example, the protective layer 170 may be in contact with the upper surface of the first PMOS conductive layer 124. For example, the protective layer 170 may be selectively formed only on the upper surface of the first PMOS conductive layer 124. That is, the protective layer 170 may not be formed on the upper surface of the first gate insulating layer 112. For example, the protective layer 170 may comprise Aniline. In some implementations, the protective layer 170 may comprise Toluene, Benzene, Pyridine, or Cyclohexane.

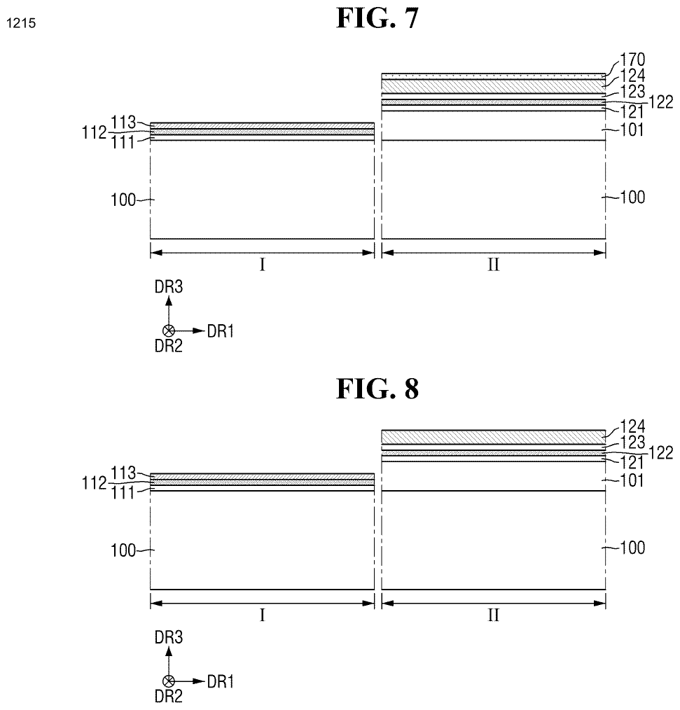

Referring to FIG. 7, the first NMOS conductive layer 113 may be formed on the upper surface of the first gate insulating layer 112. For example, the first NMOS conductive layer 113 may be in contact with the upper surface of the first gate insulating layer 112. For example, the first NMOS conductive layer 113 may be selectively formed only on the upper surface of the first gate insulating layer 112. That is, the first NMOS conductive layer 113 is not formed on the upper surface of the protective layer 170.

Referring to FIG. 8, the protective layer 170 may be removed. As a result, the first NMOS conductive layer 113 may be exposed on the upper surface of the substrate 100 in the NMOS region I. Additionally, the first PMOS conductive layer 124 may be exposed on the upper surface of the substrate 100 in the PMOS region II.

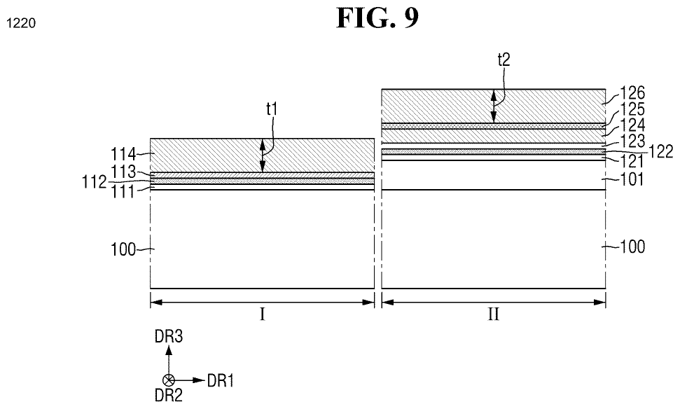

Referring to FIG. 9, the oxynitride layer 125 may be formed on the upper surface of the first PMOS conductive layer 124. For example, the oxynitride layer 125 may be in contact with the upper surface of the first PMOS conductive layer 124. For example, the oxynitride layer 125 may be formed by oxidizing a portion of the first PMOS conductive layer 124. For example, the oxynitride layer 125 is not formed on the upper surface of the first NMOS conductive layer 113.

Subsequently, the second NMOS conductive layer 114 may be formed on the upper surface of the first NMOS conductive layer 113. For example, the second NMOS conductive layer 114 may be in contact with the upper surface of the first NMOS conductive layer 113. Additionally, the second PMOS conductive layer 126 may be formed on the upper surface of the oxynitride layer 125. For example, the second PMOS conductive layer 126 may be in contact with the upper surface of the oxynitride layer 125. For example, the second NMOS conductive layer 114 and the second PMOS conductive layer 126 may be formed through the same fabricating process. For example, the thickness t2 of the second PMOS conductive layer 126 in the vertical direction DR3 may be equal to the thickness t1 of the second NMOS conductive layer 114 in the vertical direction DR3.

For example, each of the second NMOS conductive layer 114, the first PMOS conductive layer 124, and the second PMOS conductive layer 126 may comprise the same material. For example, each of the second NMOS conductive layer 114, first PMOS conductive layer 124, and second PMOS conductive layer 126 may comprise titanium nitride (TiN). In some implementations, each of the second NMOS conductive layer 114, the first PMOS conductive layer 124, and the second PMOS conductive layer 126 may comprise aluminum nitride (AlN) or titanium aluminum nitride (TiAlN).

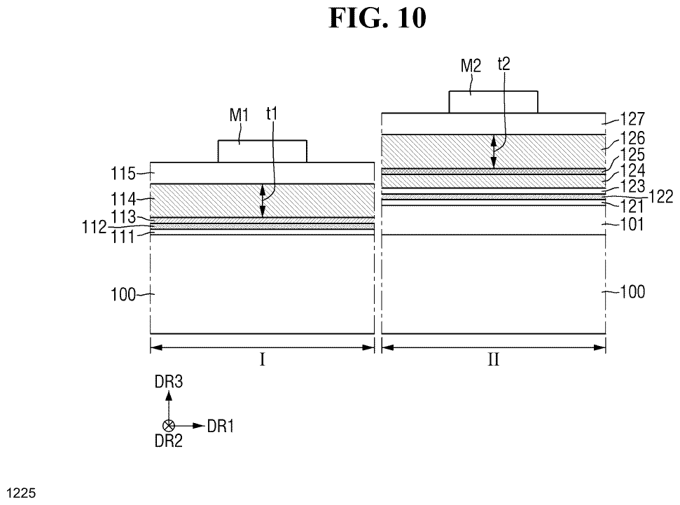

Referring to FIG. 10, the first capping layer 115 may be formed on the upper surface of the second NMOS conductive layer 114. For example, the first capping layer 115 may be in contact with the upper surface of the second NMOS conductive layer 114. Additionally, the second capping layer 127 may be formed on the upper surface of the second PMOS conductive layer 126. For example, the second capping layer 127 may be in contact with the upper surface of the second PMOS conductive layer 126. For example, the first capping layer 115 and the second capping layer 127 may be formed through the same fabricating process. Subsequently, a first mask pattern M1 may be formed on the upper surface of the first capping layer 115. Additionally, a second mask pattern M2 may be formed on the upper surface of the second capping layer 127.

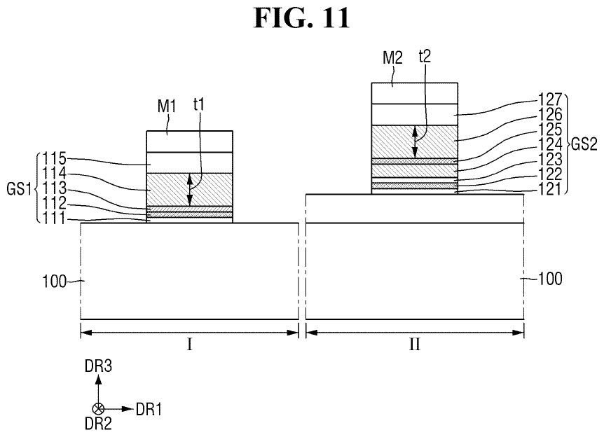

Referring to FIG. 11, patterning processes may be performed using the first mask pattern M1 and the second mask pattern M2 respectively as masks. For example, by performing the patterning process using the first mask pattern M1 as a mask, the first gate structure GS1 comprising the first interface layer 111, the first gate insulating layer 112, the first NMOS conductive layer 113, the second NMOS conductive layer 114, and the first capping layer 115 may be formed on the upper surface of the substrate 100 in the NMOS region I.

Further, by performing the patterning process using the second mask pattern M2 as a mask, the second gate structure GS2 comprising the second interface layer 121, the second gate insulating layer 122, the dielectric layer 123, the first PMOS conductive layer 124, the oxynitride layer 125, the second PMOS conductive layer 126, and the second capping layer 127 may be formed on the upper surface of the silicon-germanium layer 101 in the PMOS region II.

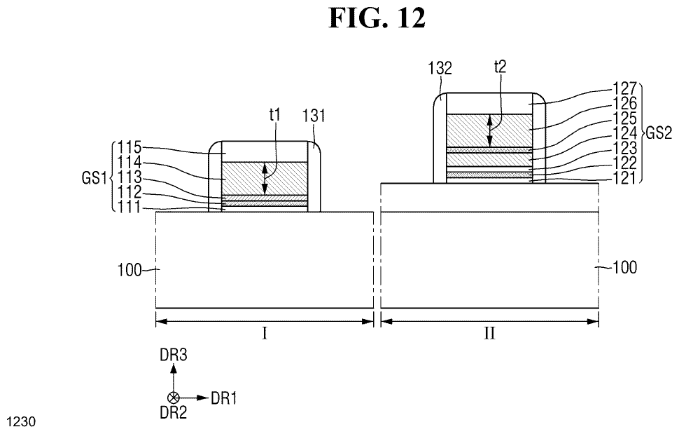

Referring to FIG. 12, each of the first mask pattern M1 in FIG. 11 and the second mask pattern M2 in FIG. 11 may be removed. Subsequently, the first gate spacer 131 may be formed on both sidewalls of the first gate structure GS1 in the first horizontal direction DR1 on the upper surface of the substrate 100 in the NMOS region I. Additionally, the second gate spacer 132 may be formed on both sidewalls of the second gate structure GS2 in the first horizontal direction DR1 on the upper surface of the silicon-germanium layer 101 in the PMOS region II.

Referring to FIG. 1, the first source/drain region 141 may be formed inside the substrate 100 in the NMOS region I. For example, the first source/drain region 141 may be formed on both sides of the first gate structure GS1 in the first horizontal direction DR1. Additionally, the second source/drain region 142 may be formed inside the silicon-germanium layer 101 in the PMOS region II. For example, the second source/drain region 142 may be formed on both sides of the second gate structure GS2 in the first horizontal direction DR1.

Subsequently, the interlayer insulating layer 150 may be formed on each of the upper surface of the substrate 100 in the NMOS region I and the upper surface of the silicon-germanium layer 101 in the PMOS region II. For example, the interlayer insulating layer 150 may cover the upper surface of the first source/drain region 141, the upper surface of the second source/drain region 142, the sidewalls and upper surface of the first gate spacer 131, the sidewalls and upper surface of the second gate spacer 132, the upper surface of the first capping layer 115, and the upper surface of the second capping layer 127.

Next, the first source/drain contact 161 connected to the first source/drain region 141 by penetrating the interlayer insulating layer 150 in the vertical direction DR3 may be formed on the upper surface of the substrate 100 in the NMOS region I. Furthermore, the second source/drain contact 162 connected to the second source/drain region 142 by penetrating the interlayer insulating layer 150 in the vertical direction DR3 may be formed on the upper surface of the substrate 100 in the PMOS region II. Through this fabricating process, the semiconductor device illustrated in FIG. 1 may be fabricated.

The method of fabricating the semiconductor device according to some implementations of the present disclosure may form the protective layer 170 on the upper surface of the first PMOS conductive layer 124 on the upper surface of the substrate 100 in the PMOS region II so that the first NMOS conductive layer 113 optionally comprising lanthanum oxide LaO is formed only on the upper surface of the substrate 100 in the NMOS region I. That is, the first NMOS conductive layer 113 is not formed on the upper surface of the substrate 100 in the PMOS region II. Accordingly, the height of the second gate structure GS2 formed on the upper surface of the substrate 100 of the PMOS region II may be reduced. That is, the step difference between the upper surface of the second gate structure GS2 formed on the upper surface of the substrate 100 in the PMOS region II and the upper surface of the first gate structure GS1 formed on the upper surface of the substrate 100 in the NMOS region I may be reduced. As a result, the method of fabricating the semiconductor device according to some implementations of the present disclosure may reduce process difficulty.

In some implementations of the semiconductor device fabricated by this method, the first gate structure GS1 formed on the upper surface of the substrate 100 in the NMOS region I comprises the first NMOS conductive layer 113 containing lanthanum oxide (LaO), while the second gate structure GS2 formed on the upper surface of the substrate 100 in the PMOS region II does not comprise the first NMOS conductive layer 113 containing lanthanum oxide (LaO). Furthermore, in the semiconductor device according to some implementations of the present disclosure, the thickness t1 in the vertical direction DR3 of the second NMOS conductive layer 114 comprised in the first gate structure GS1 and the thickness t2 in the vertical direction DR3 of the second PMOS conductive layer 126 comprised in the second gate structure GS2 may be formed to be the same. Additionally, in the semiconductor device according to some implementations of the present disclosure, the oxynitride layer 125 formed by oxidizing the portion of the first PMOS conductive layer 124 between the first PMOS conductive layer 124 comprised in the second gate structure GS2 and the second PMOS conductive layer 126 comprised in the second gate structure GS2 may be formed.

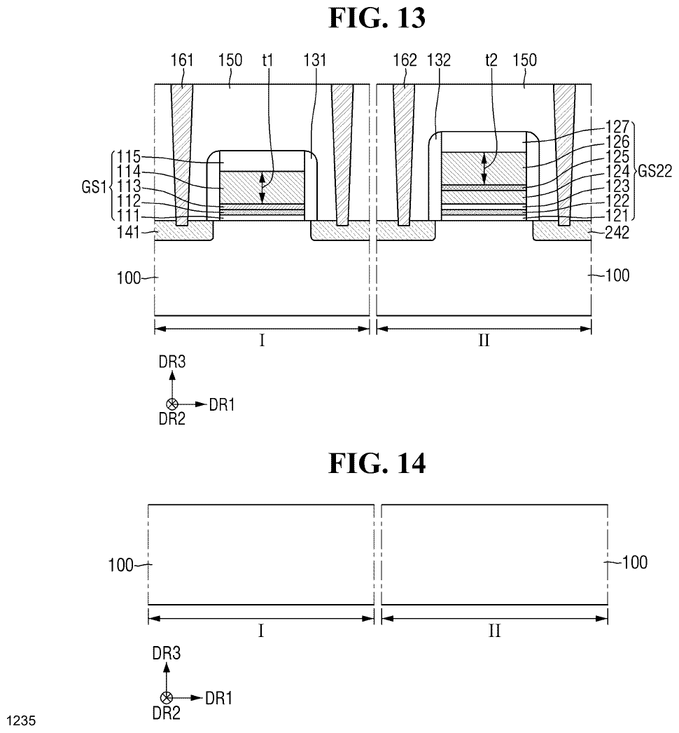

Hereinafter, referring to FIG. 13, the semiconductor device according to several implementations of the present disclosure will be described. The description will focus on differences from the semiconductor device illustrated in FIG. 1.

FIG. 13 is a diagram for explaining an example of a semiconductor device.

Referring to FIG. 13, the semiconductor device according to some implementations of the present disclosure may have the lower surface of the second gate structure GS22 being in contact with the upper surface of the substrate 100 of the PMOS region II.

For example, in the semiconductor device illustrated in FIG. 13, the silicon-germanium layer 101 in FIG. 1 is not disposed on the upper surface of the substrate 100 of the PMOS region II. For example, the lower surface of the second interface layer 121 disposed at the lowermost part of the second gate structure GS22 may be in contact with the upper surface of the substrate 100 in the PMOS region II. For example, the second source/drain region 242 may be disposed inside the substrate 100 in the PMOS region II on both sides of the second gate structure GS22 in the first horizontal direction DR1.

Hereinafter, referring to FIGS. 13 to 15, the method of fabricating the semiconductor device according to some implementations of the present disclosure will be described. The description will focus on differences from the methods of fabricating of the semiconductor devices illustrated in FIGS. 2 to 12.

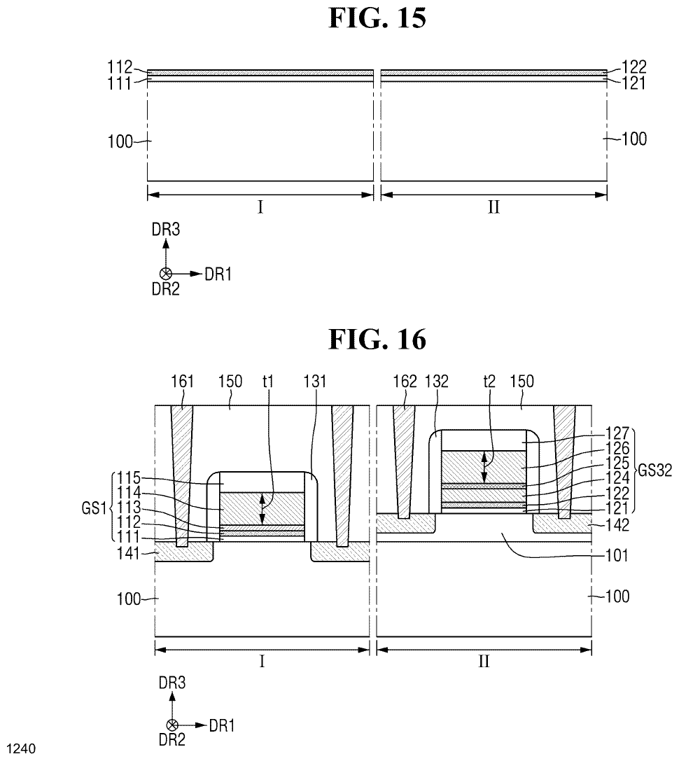

FIGS. 14 and 15 are intermediate step diagrams for explaining an example of the method of fabricating the semiconductor device.

Referring to FIG. 14, the substrate 100 comprising the NMOS region I and the PMOS region II may be provided. For example, the upper surface of the substrate 100 in the NMOS region I and the upper surface of the substrate 100 in the PMOS region II may be formed on the same plane.

Referring to FIG. 15, the first interface layer 111 and the first gate insulating layer 112 may be formed sequentially on the upper surface of the substrate 100 in the NMOS region I. For example, the first interface layer 111 may be in contact with the upper surface of the substrate 100 in the NMOS region I. The first gate insulating layer 112 may be in contact with the upper surface of the first interface layer 111. Further, the second interface layer 121 and the second gate insulating layer 122 may be formed sequentially on the upper surface of the substrate 100 in the PMOS region II. For example, the second interface layer 121 may be in contact with the upper surface of the substrate 100. The second gate insulating layer 122 may be in contact with the upper surface of the second interface layer 121. For example, the first interface layer 111 and the second interface layer 121 may be formed through the same fabricating process. Also, the first gate insulating layer 112 and the second gate insulating layer 122 may be formed through the same fabricating process. Subsequently, the fabricating processes illustrated in FIGS. 4 to 12 may be performed.

Referring to FIG. 13, the first source/drain region 141 may be formed inside the substrate 100 in the NMOS region I. For example, the first source/drain region 141 may be formed on both sides of the first gate structure GS1 in the first horizontal direction DR1. Additionally, the second source/drain region 242 may be formed inside the substrate 100 in the PMOS region II. For example, the second source/drain region 242 may be formed on both sides of the second gate structure GS22 in the first horizontal direction DR1.

Subsequently, the interlayer insulating layer 150 may be formed on the upper surface of the substrate 100 in the NMOS region I and the upper surface of the substrate 100 in the PMOS region II, respectively. For example, the interlayer insulating layer 150 may cover the upper surface of the first source/drain region 141, the upper surface of the second source/drain region 242, the sidewalls and upper surface of the first gate spacer 131, the sidewalls and upper surface of the second gate spacer 132, the upper surface of the first capping layer 115, and the upper surface of the second capping layer 127, respectively.

Additionally, the first source/drain contact 161 connected to the first source/drain region 141 by penetrating the interlayer insulating layer 150 in the vertical direction DR3 may be formed on the upper surface of the substrate 100 in the NMOS region I. Furthermore, the second source/drain contact 162 connected to the second source/drain region 242 by penetrating the interlayer insulating layer 150 in the vertical direction DR3. may be formed on the upper surface of the substrate 100 in the PMOS region II Through this fabricating process, the semiconductor device illustrated in FIG. 13 may be fabricated.

Hereinafter, referring to FIG. 16, the semiconductor device according to some implementations of the present disclosure will be described. The description will focus on differences from the semiconductor device illustrated in FIG. 1.

FIG. 16 is a diagram for explaining an example of a semiconductor device.

Referring to FIG. 16, in the semiconductor device according to some implementations of the present disclosure, the second gate structure GS32 may comprise the second interface layer 121, the second gate insulating layer 122, the first PMOS conductive layer 124, the oxynitride layer 125, the second PMOS conductive layer 126, and the second capping layer 127.

For example, in the semiconductor device illustrated in FIG. 16, the dielectric layer 123 in FIG. 1 is not disposed on the upper surface of the substrate 100 of the PMOS region II. That is, the second gate structure GS32 does not comprise the dielectric layer 123 in FIG. 1. For example, the first PMOS conductive layer 124 may be in contact with the upper surface of the second gate insulating layer 122.

Hereinafter, referring to FIGS. 16 to 18, the method of fabricating the semiconductor device according to some implementations of the present disclosure will be described. The description will focus on differences from the method of fabricating the semiconductor device illustrated in FIGS. 2 to 12.

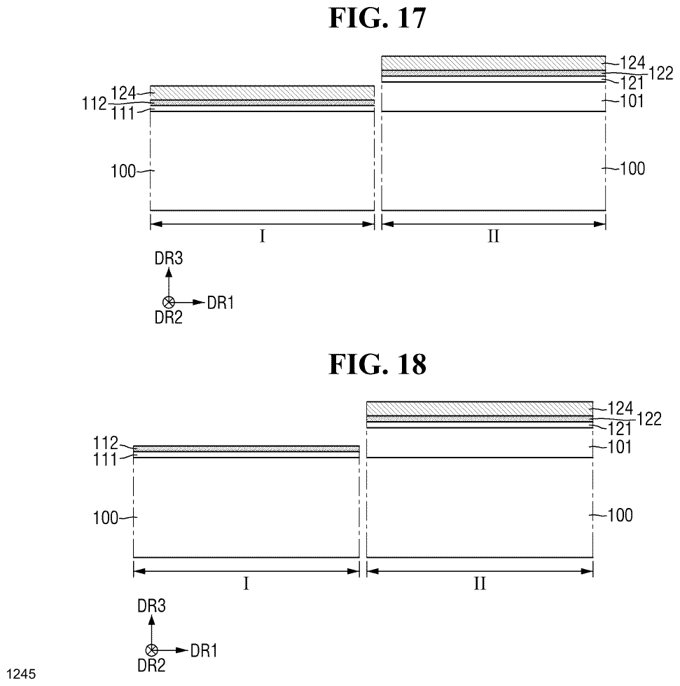

FIGS. 17 and 18 are intermediate step diagrams for explaining an example of the method of fabricating the semiconductor device.

Referring to FIG. 17, after the fabricating processes illustrated in FIGS. 2 and 3 have been performed, the first PMOS conductive layer 124 may be formed on the upper surface of the first gate insulating layer 112 and the upper surface of the second gate insulating layer 122, respectively. For example, the first PMOS conductive layer 124 may be in contact with the upper surface of the first gate insulating layer 112 and the upper surface of the second gate insulating layer 122, respectively.

Referring to FIG. 18, the first PMOS conductive layer 124 formed on the upper surface of the first gate insulating layer 112 may be removed. That is, the first PMOS conductive layer 124 formed on the upper surface of the second gate insulating layer 122 is not removed. Subsequently, the fabricating processes illustrated in FIGS. 6 to 12 may be performed.

Referring to FIG. 16, the first source/drain region 141 may be formed inside the substrate 100 in the NMOS region I. For example, the first source/drain region 141 may be formed on both sides of the first gate structure GS1 in the first horizontal direction DR1. Further, the second source/drain region 142 may be formed inside the silicon-germanium layer 101 in the PMOS region II. For example, the second source/drain region 142 may be formed on both sides of the second gate structure GS32 in the first horizontal direction DR1.

Subsequently, the interlayer insulating layer 150 may be formed on each of the upper surface of the substrate 100 in the NMOS region I and the upper surface of the silicon-germanium layer 101 in the PMOS region II. For example, the interlayer insulating layer 150 may cover the upper surface of the first source/drain region 141, the upper surface of the second source/drain region 142, the sidewalls and the upper surface of the first gate spacer 131, the sidewalls and the upper surface of the second gate spacer 132, the upper surface of the first capping layer 115, and the upper surface of the second capping layer 127, respectively.

Then, the first source/drain contact 161 connected to the first source/drain region 141 by penetrating the interlayer insulating layer 150 in the vertical direction DR3 may be formed on the upper surface of the substrate 100 in the NMOS region I. Additionally, the second source/drain contact 162 connected to the second source/drain region 142 by penetrating the interlayer insulating layer 150 in the vertical direction DR3 may be formed on the upper surface of the silicon-germanium layer 101 in the PMOS region II. Through this fabricating process, the semiconductor device illustrated in FIG. 16 may be fabricated.

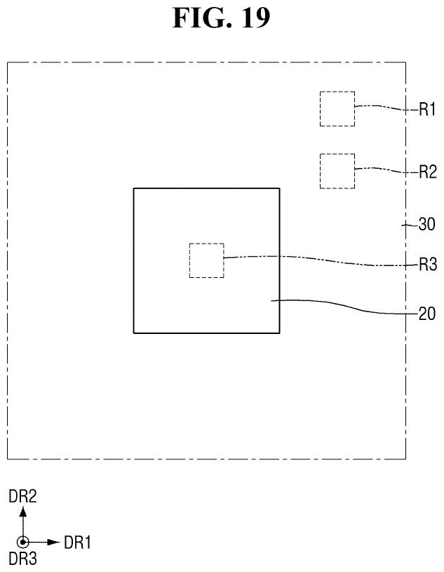

Hereinafter, the semiconductor device according to some implementations of the present disclosure will be described with reference to FIGS. 19 to 22. The description will focus on differences from the semiconductor device illustrated in FIG. 1.

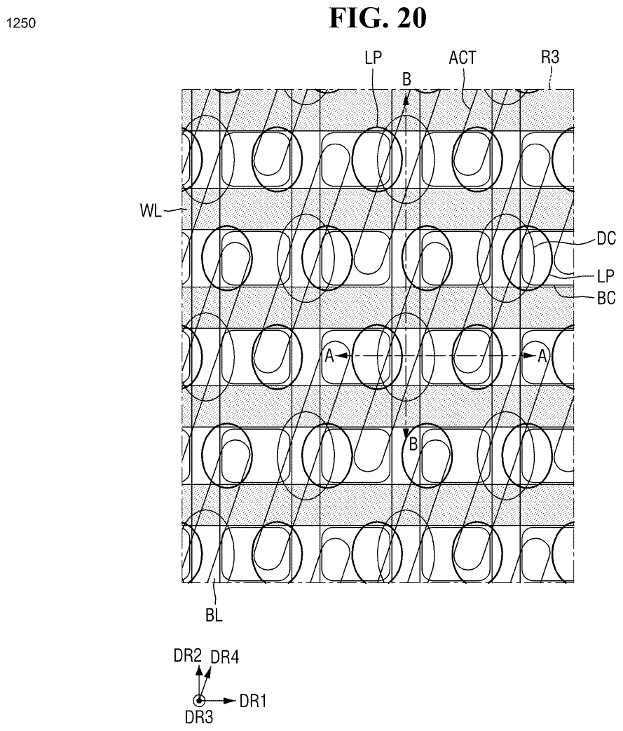

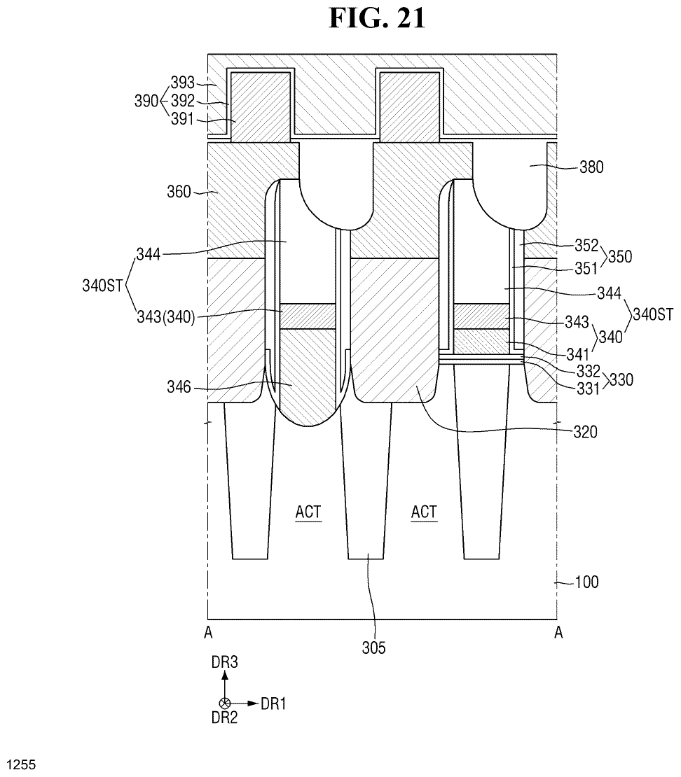

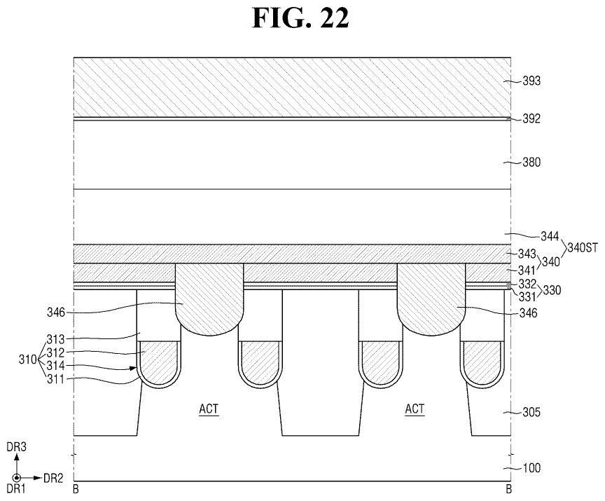

FIG. 19 is a schematic layout view of an example of the semiconductor device. FIG. 20 is an example enlarged schematic layout view of a portion R3 in FIG. 19. FIG. 21 is an example cross-sectional view taken along line A-A in FIG. 20. FIG. 22 is an example cross-sectional view taken along line B-B in FIG. 20.

Referring to FIG. 19, the semiconductor device according to some implementations of the present disclosure may comprise a cell region 20 and a peripheral region 30 defined around the cell region 20. For example, the substrate 100 in FIG. 1 may comprise the cell region 20 and the peripheral region 30. For example, the cell region 20 may be the region where memory cells are disposed. The peripheral region 30 may be the region where circuits for operating the memory cells in the cell region 20 are disposed.

For example, the cross-sectional view taken along a portion R1 in FIG. 19 in the first horizontal direction DR1 may correspond to the NMOS region I in each of FIGS. 1, 13, and 16. Furthermore, the cross-sectional view taken along a portion R2 in FIG. 19 in the first horizontal direction DR1 may correspond to the PMOS region II in each of FIGS. 1, 13, and 16. That is, the semiconductor devices illustrated in each in FIGS. 1, 13, and 16 may be disposed in the peripheral region 30 in FIG. 19. Therefore, a detailed description of the portion R1 and the portion R2 in FIG. 19 is omitted. Hereinafter, the portion R3 in FIG. 19 will be mainly described.

Referring to FIG. 20, the semiconductor device according to some implementations of the present disclosure may comprise a plurality of active regions ACT. The active regions ACT may be defined by a device isolation layer 305 in FIG. 21 formed in the substrate 100 in FIG. 21. In accordance with decreasing design rules for semiconductor devices, the active region ACT may be disposed in the shape of a bar of diagonal lines or oblique lines, as illustrated in FIG. 20. The active region ACT may have a bar shape extending in the third horizontal direction DR4. For example, the third horizontal direction DR4 may be defined as a direction parallel to the upper surface of the substrate 100 in FIG. 21. Additionally, the third horizontal direction DR4 may be defined as a direction having an acute angle to each of the first horizontal direction DR1 and the second horizontal direction DR2.

On the active region ACT, a plurality of gate electrodes may be disposed in the first horizontal direction DR1 across the active region ACT. The plurality of gate electrodes may extend parallel to each other. The plurality of gate electrodes may be, for example, a plurality of word lines WL. The word lines WLs may be equally spaced apart. The width of the word lines WLs or the spacing between the word lines WL may be determined by design rules.

A plurality of bit lines BL extending in the second horizontal direction DR2 orthogonal to the word lines WL may be disposed on the word lines WL. The plurality of bit lines BL may extend in the second horizontal direction DR2 across the active region ACT. The plurality of bit lines BL may extend parallel to each other. The bit lines BL may be equally spaced apart. The width of the bit lines BL or the spacing between the bit lines BL may be determined according to design rules.

In some implementations, the semiconductor device may comprise various contact arrays formed on an active region ACT. The various contact arrays may comprise, for example, a direct contact DC, a buried contact BC, and a landing pad LP. Here, the direct contact DC may refer to a contact that electrically connects the active region ACT to the bit line BL. The buried contact BC may refer to a contact that connects the active region ACT to a lower electrode 391 in FIG. 21. in a capacitor 390 in FIG. 21.

Due to the arrangement structure, the contact region of the buried contact BC and the active region ACT may be small. Accordingly, a conductive landing pad LP may be introduced to expand the contact region with the active region ACT, as well as to expand the contact region with the lower electrode 391 in FIG. 21 of the capacitor. The landing pad LP may be disposed between the active region ACT and the buried contact BC, or between the buried contact BC and the lower electrode 391 in FIG. 21 of the capacitor. In the semiconductor device according to some implementations of the present disclosure, the landing pad LP may be disposed between the buried contact BC and the lower electrode 391 in FIG. 21 of the capacitor. By expanding the contact region through the introduction of the landing pad LP, the contact resistance between the active region ACT and the lower electrode 391 in FIG. 21 of the capacitor may be reduced.

In some implementations, the direct contact DC may be disposed in the center portion of the active region ACT. The buried contact BC may be disposed at both end portions of the active region ACT. As the buried contact BC is disposed at both end portions of the active region ACT, the landing pads LP may be disposed adjacent to both end portions of the active region ACT to partially overlap the buried contacts BC. In other words, the buried contact BC may be formed to overlap the active region ACT and the device isolation layer 305 in FIG. 21 between the adjacent word lines WL and the adjacent bit lines BL. The word line WL may be formed to be buried in the substrate 100 in FIG. 21. The word line WL may be disposed across the active region ACT between the direct contact DC and the buried contact BC. As illustrated, two word lines WL may be disposed to cross one active region ACT. As the active region ACT is disposed in a diagonal shape, the word line WL may have an angle of less than 90 degrees to the active region ACT.

The direct contact DC and the buried contact BC may be symmetrically disposed. Accordingly, the direct contact DC and the buried contact BC may be disposed in a straight line along the first horizontal direction DR1 and the second horizontal direction DR2. However, unlike the direct contact DC and the buried contact BC, the landing pad LP may be disposed in a zigzag pattern along the second horizontal direction DR2 in which the bit line BL extends. Additionally, the landing pad LP may be disposed to overlap the same side portion of each bit line BL in the first horizontal direction DR1 in which the word line WL extends. For example, each landing pad LP of the first line may overlap the left side of the corresponding bit line BL, and each landing pad LP of the second line may overlap the right side of the corresponding bit line BL.

Referring to FIGS. 20 to 22, the semiconductor device according to some implementations of the present disclosure may comprise a device isolation layer 305, a plurality of gate structures 310, a plurality of bit line structures 340ST, a bit line contact 346, a storage contact 320, and a capacitor 190.

The active region ACT defined by the device isolation layer 305 may have a long island formation comprising a short axis and a long axis, as illustrated in FIG. 20. The active region ACT may have an oblique shape to have an angle of less than 90 degrees with respect to the word line WL formed in the device isolation layer 305. Additionally, the active region ACT may have an oblique shape to have an angle of less than 90 degrees with respect to the bit line BL formed on the device isolation layer 305.

The gate structures 310 may be formed in the substrate 100 and the device isolation layer 305. The gate structures 310 may be formed across the device isolation layer 305 and the active region ACT defined by the device isolation layer 305. That is, one gate structure 310 may be formed in the substrate 100 and the device isolation layer 305 positioned in the first horizontal direction DR1 in which the gate structure 310 extends. The gate structure 310 may comprise a gate trench 314, a third gate insulating layer 311, a first gate electrode 312, and a gate capping pattern 313 formed in the substrate 100 and device isolation layer 305. Here, the first gate electrode 312 may correspond to the word line WL.

The third gate insulating layer 311 may extend along the sidewalls and bottom surface of the gate trench 314. The third gate insulating layer 311 may comprise at least one of silicon oxide, silicon nitride, silicon oxynitride, or a high-k material having a dielectric constant higher than a silicon oxide. The high-k material may be the same as described for the first and second gate insulating layers 112, 122 in FIG. 1.

The first gate electrode 312 may be formed on the third gate insulating layer 311. The first gate electrode 312 may fill the portion of the gate trench 314. The first gate electrode 312 may comprise at least one of metal, conductive metal nitride, conductive metal carbonitride, conductive metal carbide, a metal silicide, a doped semiconductor material, a conductive metal oxynitride, and a conductive metal oxide. The first gate electrode 312 may be made of, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited thereto. Although not illustrated, an impurity doped region may be formed on at least one side of the gate structure 310. The impurity doped region may be the source/drain region of the transistor. The gate capping pattern 313 may be formed on the first gate electrode 312. The gate capping pattern 313 may fill the remaining gate trench 314 in which the first gate electrode 312 is formed. The gate capping pattern 313 comprises an insulating material.

The bit line structure 340ST may comprise a cell conductive line 340 and a cell line capping layer 344. The cell conductive line 340 may be formed on the substrate 100 and the device isolation layer 305 on which the gate structure 310 is formed. The cell conductive line 340 may cross the device isolation layer 305 and an active region ACT defined by the device isolation layer 305. One cell conductive line 340 may be formed on the substrate 100 and the device isolation layer 305 disposed in the second horizontal direction DR2 in which the cell conductive line 340 extends. The cell conductive line 340 may be formed to cross the gate structure 310. Here, the cell conductive line 340 may correspond to the bit line BL. The cell conductive line 340 may comprise a lower cell conductive line 341 and an upper cell conductive line 342 on the lower cell conductive line 341. Each of the lower cell conductive line 341 and the upper cell conductive line 342 may comprise a conductive material.

The bit line contact 346 may be formed between the cell conductive line 340 and the substrate 100. That is, the cell conductive line 340 may be formed on the bit line contact 346. For example, the bit line contact 346 may be formed at a point where cell conductive line 340 crosses a center portion of the active region ACT having a long island shape. The bit line contact 346 may be formed between the substrate 100 in the center portion of the active region ACT and the cell conductive line 340. The bit line contact 346 may electrically connect the cell conductive line 340 and the substrate 100. Through the bit line contact 346, the bit line structure 340ST may be connected to the active region ACT. Bit line contact 346 may correspond to a direct contact DC. The bit line contact 346 may comprise, for example, at least one of an impurity doped semiconductor material, a conductive silicide compound, a conductive metal nitride, a conductive metal oxide, and a metal.

The cell line capping layer 344 may be disposed on the cell conductive line 340. The cell line capping layer 344 comprises an insulating material. The cell insulating layer 330 may be formed on the substrate 100 and the device isolation layer 305. The cell insulating layer 330 may be formed on the substrate 100 and the device isolation layer 305 where the bit line contact 346 is not formed. The cell insulating layer 330 may be formed between the substrate 100 and the cell conductive line 340, and between the device isolation layer 305 and the cell conductive line 340. The cell insulating layer 330 may be a single layer, but as illustrated, the cell insulating layer 330 may also be a multilayer comprising the first cell insulating layer 331 and the second cell insulating layer 332. For example, the first cell insulating layer 331 may comprise an oxide layer, and the second cell insulating layer 332 may comprise a nitride layer, but the present disclosure is not limited thereto.

The cell line spacer 350 may be disposed on sidewalls of the cell conductive line 340 and the cell line capping layer 344. The cell line spacer 350 may be a single layer, but as illustrated, the cell line spacer 350 may also be a multilayer comprising the first cell line spacer 351 and the second cell line spacer 352. For example, the first and second cell line spacers 351, 352 may comprise one of a silicon oxide layer, a silicon nitride layer, a silicon oxynitride layer (SiON), a silicon oxycarbonitride layer (SiOCN), air, and combinations thereof, but the present disclosure is not limited thereto.

The storage contact 320 may be formed between adjacent cell conductive lines 340. The storage contact 320 may overlap the substrate 100 and the device isolation layer 305 between the adjacent cell conductive lines 340. Here, the storage contact 320 may correspond to the buried contact BC. The storage contact 320 may comprise, for example, at least one of an impurity doped semiconductor material, a conductive silicide compound, a conductive metal nitride, a conductive metal oxide, and a metal.

The storage pad 360 may be formed on the storage contact 320. The storage pad 360 may be electrically connected to the storage contact 320. Here, the storage pad 360 may correspond to the landing pad LP. The storage pad 360 may comprise, for example, at least one of an impurity doped semiconductor material, a conductive silicide compound, a conductive metal nitride, a conductive metal oxide, and a metal.

The pad isolation insulating layer 380 may be formed on the storage pad 360 and the bit line structure 340ST. For example, the pad isolation insulating layer 380 may be disposed on the cell line capping layer 344. The pad isolation insulating layer 380 may define regions of the storage pad 360 that form a plurality of isolated regions. Further, the pad isolation insulating layer 380 may be patterned to expose at least a portion of the upper surface of the storage pad 360. The pad isolation insulating layer 380 comprises an insulating material.

The capacitor 390 may be formed in the pad isolation insulating layer 380. The capacitor 390 may be electrically connected to the storage contact 320 through the storage pad 360. The capacitor 390 comprises the lower electrode 391, a capacitor dielectric layer 392, and an upper electrode 393. The lower electrode 391 may be disposed on the storage pad 360. The lower electrode 391 is illustrated as having a pillar shape, but the present disclosure is not limited thereto. The lower electrode 391 may of course have a cylinder shape. The capacitor dielectric layer 392 is formed on the lower electrode 391. The capacitor dielectric layer 392 may be formed along the profile of the lower electrode 391. The upper electrode 393 is formed on the capacitor dielectric layer 392. The upper electrode 393 may surround the outer sidewall of the lower electrode 391.

The lower electrode 391 and the upper electrode 393 may each comprise, for example, doped semiconductor materials, conductive metal nitrides such as titanium nitride, tantalum nitride, niobium nitride, or tungsten nitride, etc., metals such as ruthenium, iridium, titanium, or tantalum, etc., and conductive metal oxides such as iridium oxide or niobium oxide, etc., but not limited thereto.

The capacitor dielectric layer 392 may comprise, for example, silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, and titanium oxide, barium strontium titanium oxide, barium titanium oxide, strontium titanium oxide, yttrium oxide, aluminum oxide, lead scandium tantalum oxide, lead zinc niobate, and combinations thereof, but not limited thereto.

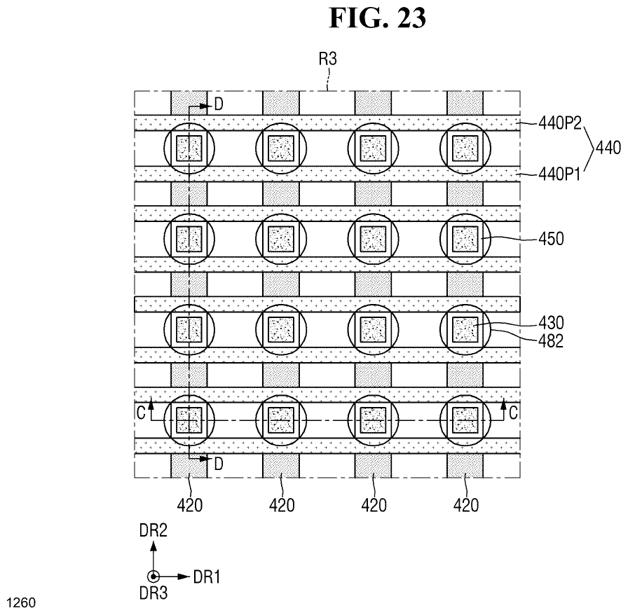

Hereinafter, referring to FIGS. 23 to 25, the semiconductor device according to some implementations of the present disclosure will be described. The description will focus on differences between the semiconductor devices illustrated in FIGS. 20 to 22.

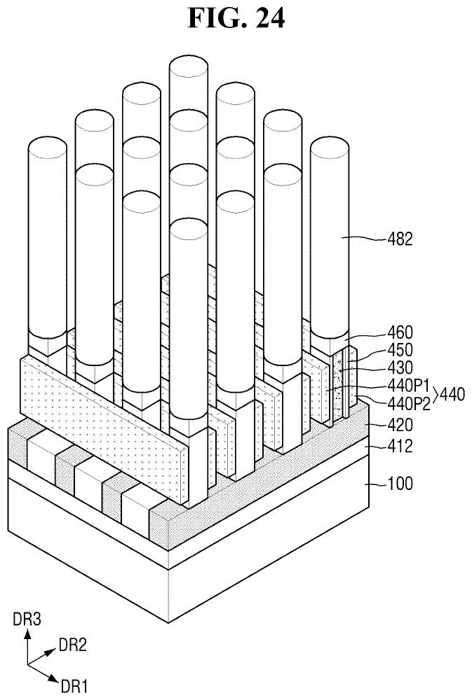

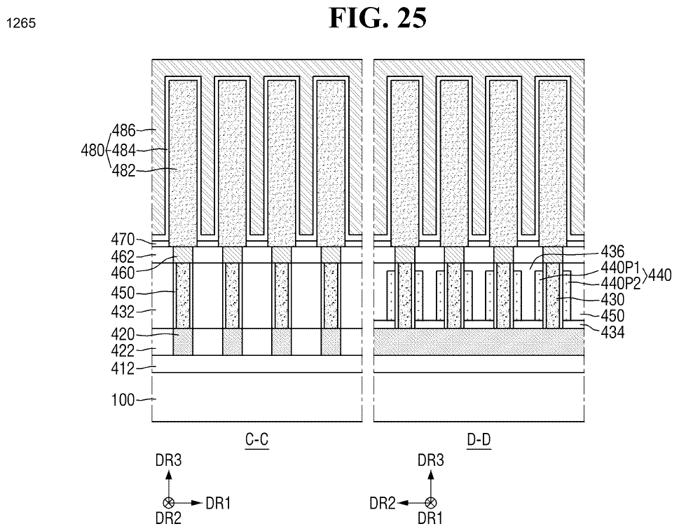

FIG. 23 is a layout diagram for explaining an example of the semiconductor device. FIG. 24 is a perspective view for explaining an example of the semiconductor device. FIG. 25 is an example cross-sectional view taken along each of the lines C-C and D-D in FIG. 23.

Referring to FIGS. 23 to 25, the semiconductor device according to some implementations of the present disclosure may comprise the substrate 100, a plurality of first conductive lines 420, a channel layer 430, a gate electrode 440, a fourth gate insulating layer 450, and a capacitor 480. The semiconductor device according to some implementations may be a memory device comprising a vertical channel transistor VCT. The vertical channel transistor may refer to a structure in which the channel length of the channel layer 430 extends along a vertical direction from the substrate 100.

A lower insulating layer 412 may be disposed on the substrate 100. The plurality of first conductive lines 420 on the lower insulating layer 412 may be spaced apart from each other in the first horizontal direction DR1 and extend in the second horizontal direction DR2. A plurality of first insulating patterns 422 may be disposed on the lower insulating layer 412 to fill the space between the plurality of first conductive lines 420. The plurality of first insulating patterns 422 may extend in the second horizontal direction DR2. The upper surface of the plurality of first insulating patterns 422 may be disposed at the same level as the upper surface of the plurality of first conductive lines 420. The plurality of first conductive lines 420 may function as bit lines.

The plurality of first conductive lines 420 may comprise doped semiconductor materials, metals, conductive metal nitrides, conductive metal silicides, conductive metal oxides, or combinations thereof. For example, the plurality of first conductive lines 420 may comprise doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but are not limited thereto. The plurality of first conductive lines 420 may comprise a single layer or multiple layers of the materials described above. In some implementations, the plurality of first conductive lines 420 may comprise graphene, carbon nanotube, or combinations thereof.

The channel layer 430 may be arranged in a matrix form spaced apart in a first horizontal direction DR1 and a second horizontal direction DR2 on the plurality of first conductive lines 420. The channel layer 430 may have a first width along the first horizontal direction DR1 and a first height along the vertical direction DR3, wherein the first height may be greater than the first width. For example, the first height may be about 2 to 10 times the first width, but the present disclosure is not limited thereto. The bottom portion of the channel layer 430 may function as a third source/drain region, the upper portion of the channel layer 430 may function as a fourth source/drain region, and the portion of the channel layer 430 between the third and fourth source/drain regions may function as a channel region.

In some implementations, the channel layer 430 may comprise an oxide semiconductor, for example, the oxide semiconductor may comprise InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or combinations thereof. The channel layer 430 may comprise a single layer or multiple layers of the oxide semiconductor. In some implementations, the channel layer 430 may have a bandgap energy greater than the bandgap energy of silicon. For example, the channel layer 430 may have a bandgap energy of about 1.5 eV to 5.6 eV. For example, the channel layer 430 may have optimal channel performance when it has a bandgap energy of about 2.0 eV to 4.0 eV. For example, the channel layer 430 may be polycrystalline or amorphous, but are not limited thereto. In some implementations, the channel layer 430 may comprise graphene, carbon nanotubes, or combinations thereof.

The gate electrode 440 may extend in the first horizontal direction DR1 on both sidewalls of the channel layer 430. The gate electrode 440 may comprise a first sub-gate electrode 440P1 facing the first sidewall of the channel layer 430, and a second sub-gate electrode 440P2 facing the second sidewall opposite the first sidewall of the channel layer 430. As one channel layer 430 is disposed between the first sub-gate electrode 440P1 and the second sub-gate electrode 440P2, the semiconductor device may have a dual-gate transistor structure. However, the present disclosure is not limited thereto, and a single-gate transistor structure may be realized by omitting the second sub-gate electrode 440P2 and forming only the first sub-gate electrode 440P1 facing the first sidewall of the channel layer 430. The material comprised in the gate electrode 440 may be the same as described for the first gate electrode 312 in FIG. 22.

The fourth gate insulating layer 450 may surround sidewalls of the channel layer 430 and may be interposed between the channel layer 430 and the gate electrode 440. For example, as illustrated in FIG. 23, the entire sidewalls of the channel layer 430 may be surrounded by the fourth gate insulating layer 450, and a portion of the sidewall of the gate electrode 440 may be in contact with the fourth gate insulating layer 450. In some implementations, the fourth gate insulating layer 450 may extend in the extending direction of the gate electrode 440 (i.e., the first horizontal direction DR1), and only the two sidewalls of the channel layer 430 facing the gate electrode 440 may be in contact with the fourth gate insulating layer 450. For example, the fourth gate insulating layer 450 may comprise a silicon oxide layer, a silicon oxynitride layer, a high-k material having a higher dielectric constant than the silicon oxide layer, or combinations thereof.

A plurality of second insulating patterns 432 may extend in the second horizontal direction DR2 on the plurality of first insulating patterns 422. The channel layer 430 may be disposed between two adjacent second insulating patterns 432 of the plurality of second insulating patterns 432. Additionally, between the two adjacent second insulating patterns 432, a first buried layer 434 and a second buried layer 436 may be disposed in the space between the two adjacent channel layers 430. The first buried layer 434 may be disposed at the bottom of the space between the two adjacent channel layers 430. The second buried layer 436 may be formed to fill the remainder of the space between the two adjacent channel layers 430 on an upper surface of the first buried layer 434. The upper surface of the second buried layer 436 may be disposed at the same level as the upper surface of the channel layer 430, and the second buried layer 436 may cover the upper surface of the gate electrode 440. Alternatively, the plurality of second insulating patterns 432 may be formed as continuous material layers with the plurality of first insulating patterns 422, or the second buried layer 436 may be formed as a continuous material layer with the first buried layer 434.

A capacitor contact 460 may be disposed on the channel layer 430. The capacitor contact 460 may be disposed to vertically overlap the channel layer 430, and may be arranged in a matrix form spaced apart in a first horizontal direction DR1 and a second horizontal direction DR2. The capacitor contact 460 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but are not limited thereto. The upper insulating layer 462 may surround the sidewalls of the capacitor contact 460 on the plurality of second insulating patterns 432 and the second buried layer 436.

An etch stop layer 470 may be disposed on the upper insulating layer 462. A capacitor 480 may be disposed on the etch stop layer 470. The capacitor 480 may comprise a lower electrode 482, a capacitor dielectric layer 484, and an upper electrode 486. The lower electrode 482 may penetrate the etch stop layer 470 and be electrically connected to the upper surface of the capacitor contact 460. The lower electrode 482 may be formed as a pillar type extending in the vertical direction DR3, but the present disclosure is not limited thereto. For example, the lower electrode 482 may be disposed to vertically overlap the capacitor contact 460 and arranged in a matrix form spaced apart in the first horizontal direction DR1 and the second horizontal direction DR2. Alternatively, a landing pad may be further disposed between the capacitor contact 460 and the lower electrode 482, so that the lower electrode 482 may be arranged in a hexagonal shape.

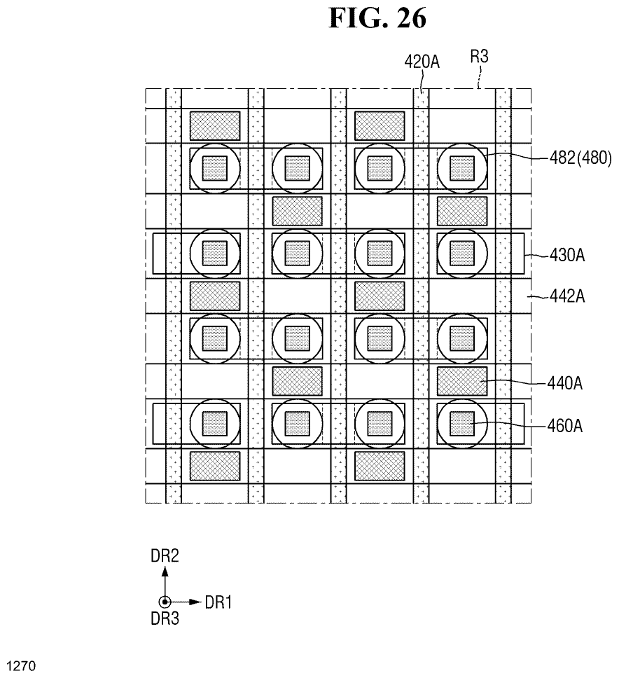

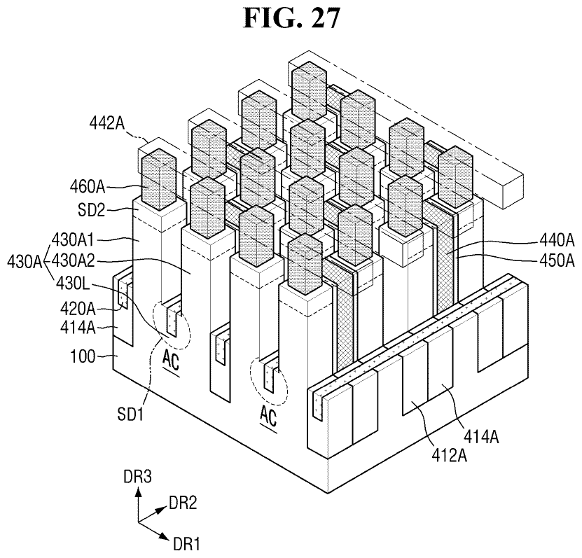

Hereinafter, referring to FIGS. 26 and 27, the semiconductor device according to some implementations of the present disclosure will be described. The description will focus on differences between the semiconductor devices illustrated in FIGS. 20 and 22.

FIG. 26 is a layout diagram for explaining an example of the semiconductor device. FIG. 27 is a perspective view for explaining an example of the semiconductor device.

Referring to FIGS. 26 and 27, the semiconductor device according to some implementations of the present disclosure may comprise the substrate 100, a plurality of first conductive lines 420A, a channel structure 430A, a contact gate electrode 440A, a plurality of second conductive lines 442A, and the capacitor 480. The semiconductor device according to some implementations of the present disclosure may be a memory device comprising a vertical channel transistor VCT.

The plurality of active regions AC may be defined in the substrate 100 by the first device isolation pattern 412A and the device isolation pattern 414A. The channel structures 430A may be disposed in each of the active regions AC. The channel structure 430A may comprise a first active pillar 430A1 and a second active pillar 430A2 respectively extending in a vertical direction, and a connection part 430L connecting a bottom portion of the first active pillar 430A1 and a bottom portion of the second active pillar 430A2. A fifth source/drain region SD1 may be disposed in the connection part 430L. A sixth source/drain region SD2 may be disposed on the upper side of the first and second active pillars 430A1, 430A2. The first active pillar 430A1 and the second active pillar 430A2 may constitute independent unit memory cells, respectively.

The plurality of first conductive lines 420A may extend in a direction crossing each of the plurality of active regions AC, such as in the second horizontal direction DR2. One first conductive line 420A of the plurality of first conductive lines 420A may be disposed on the connection part 430L between the first active pillar 430A1 and the second active pillar 430A2. One first conductive line 420A may be disposed on the fifth source/drain region SD1. Another first conductive line 420A adjacent to one first conductive line 420A may be disposed between two channel structures 430A. One first conductive line 420A of the plurality of first conductive lines 420A may function as a common bit line comprised in two unit memory cells comprising the first active pillar 430A1 and the second active pillar 430A2 disposed on either side of the one first conductive line 420A.

One contact gate electrode 440A may be disposed between two channel structures 430A adjacent in the second horizontal direction DR2. For example, the contact gate electrode 440A may be disposed between the first active pillar 430A1 comprised in one channel structure 430A and the second active pillar 430A2 of the channel structure 430A adjacent thereto. One contact gate electrode 440A may be shared by the first active pillar 430A1 and the second active pillar 430A2 disposed on both sidewalls thereof. The fourth gate insulating layer 450A may be disposed between the contact gate electrode 440A and the first active pillar 430A1 and between the contact gate electrode 440A and the second active pillar 430A2. The plurality of second conductive lines 442A may extend in the first horizontal direction DR1 on the upper surface of the contact gate electrode 440A. The plurality of second conductive lines 442A may function as word lines of the semiconductor device.

A capacitor contact 460A may be disposed on the channel structure 430A. The capacitor contact 460A may be disposed on the sixth source/drain region SD2, and the capacitor 480 may be disposed on the capacitor contact 460A.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While implementations according to the present disclosure have been described above with reference to the accompanying drawings, it will be understood that the present disclosure is not limited to the above implementations and may be fabricated in a variety of different forms, and those skilled in the art to which the present disclosure belongs, with ordinary knowledge in the field, may recognize that it may be implemented in other specific form without changing the technical idea or essential features of the present disclosure. Therefore, it should be understood that the above-described implementations are exemplary in all respects and not restrictive.

What is claimed is:

1. A semiconductor device comprising:
a substrate comprising an n-channel metal-oxide semiconductor (NMOS) region and a p-channel metal-oxide semiconductor (PMOS) region;
a first gate insulating layer disposed on an upper surface of the substrate in the NMOS region,
a first NMOS conductive layer in contact with an upper surface of the first gate insulating layer, the first NMOS conductive layer comprising lanthanum oxide (LaO);
a second NMOS conductive layer in contact with an upper surface of the first NMOS conductive layer;
a second gate insulating layer disposed on the upper surface of the substrate in the PMOS region;
a first PMOS conductive layer disposed on an upper surface of the second gate insulating layer;
a second PMOS conductive layer disposed on an upper surface of the first PMOS conductive layer; and
an oxynitride layer disposed between the first PMOS conductive layer and the second PMOS conductive layer, the oxynitride layer in contact with each of the first PMOS conductive layer and the second PMOS conductive layer,
wherein the second NMOS conductive layer, the first PMOS conductive layer, and the second PMOS conductive layer comprises the same material, and
wherein a thickness of the second PMOS conductive layer in a vertical direction is the same as a thickness of the second NMOS conductive layer in the vertical direction.

2. The semiconductor device of claim 1, wherein the second NMOS conductive layer comprises titanium nitride (TiN), the first PMOS conductive layer comprises TiN, and the second PMOS conductive layer comprises TiN.

3. The semiconductor device of claim 1, wherein the oxynitride layer comprises titanium oxynitride (TiON).

4. The semiconductor device of claim 1, wherein an upper surface of the second PMOS conductive layer is higher than an upper surface of the second NMOS conductive layer.

5. The semiconductor device of claim 1, comprising:
a dielectric layer disposed between the second gate insulating layer and the first PMOS conductive layer, the dielectric layer in contact with each of the second gate insulating layer and the first PMOS conductive layer.

6. The semiconductor device of claim 5, wherein the dielectric layer comprises aluminum oxide (AlO).

7. The semiconductor device of claim 1, comprising:
a silicon-germanium layer disposed between the upper surface of the substrate in the PMOS region and the second gate insulating layer, the silicon-germanium layer comprising silicon germanium (SiGe).

8. The semiconductor device of claim 7, wherein an upper surface of the silicon-germanium layer is higher than the upper surface of the substrate in the NMOS region.

9. A method of fabricating a semiconductor device comprising:
providing a substrate, the substrate comprising an n-channel metal-oxide semiconductor (NMOS) region and a p-channel metal-oxide semiconductor (PMOS) region;
forming a first gate insulating layer on an upper surface of the substrate in the NMOS region, and forming a second gate insulating layer on the upper surface of the substrate in the PMOS region;
forming a first PMOS conductive layer on an upper surface of the second gate insulating layer;
forming a protective layer, the protective layer contacting an upper surface of the first PMOS conductive layer;
forming a first NMOS conductive layer, the first NMOS conductive layer contacting an upper surface of the first gate insulating layer, the first NMOS conductive layer comprising lanthanum oxide (LaO);
removing the protective layer;
forming an oxynitride layer, the oxynitride layer contacting the upper surface of the first PMOS conductive layer; and
forming a second NMOS conductive layer, the second NMOS conductive layer contacting an upper surface of the first NMOS conductive layer, and forming a second PMOS conductive layer, the second PMOS conductive layer contacting an upper surface of the oxynitride layer,
wherein the second NMOS conductive layer, the first PMOS conductive layer, and the second PMOS conductive layer comprises the same material.

10. The method of fabricating the semiconductor device of claim 9, wherein a thickness of the second PMOS conductive layer in a vertical direction is the same as a thickness of the second NMOS conductive layer in the vertical direction.

11. The method of fabricating the semiconductor device of claim 9, wherein the second NMOS conductive layer comprises titanium nitride (TiN), the first PMOS conductive layer comprises TiN, and the second PMOS conductive layer comprises TiN, and
wherein the oxynitride layer comprises titanium oxynitride (TiON).

12. The method of fabricating a semiconductor device of claim 9, wherein the protective layer comprises Aniline.

13. The method of fabricating the semiconductor device of claim 9, wherein forming the first PMOS conductive layer on the upper surface of the second gate insulating layer comprises
forming the first PMOS conductive layer, the first PMOS conductive layer contacting the upper surface of the first gate insulating layer and the upper surface of the second gate insulating layer, and
removing the first PMOS conductive layer that is formed on the upper surface of the first gate insulating layer.

14. The method of fabricating the semiconductor device of claim 9, comprising:
after the second NMOS conductive layer is formed, forming a first gate structure based on patterning the first gate insulating layer, the first NMOS conductive layer, and the second NMOS conductive layer, and
after the second PMOS conductive layer is formed, forming a second gate structure based on patterning the second gate insulating layer, the first PMOS conductive layer, the oxynitride layer, and the second PMOS conductive layer.

15. The method of fabricating the semiconductor device of claim 9, wherein forming the first PMOS conductive layer on the upper surface of the second gate insulating layer comprises
forming a dielectric layer contacting the upper surface of the first gate insulating layer and the upper surface of the second gate insulating layer,
forming the first PMOS conductive layer contacting an upper surface of the dielectric layer, and
removing the dielectric layer and the first PMOS conductive layer that are formed on the upper surface of the first gate insulating layer.

16. The method of fabricating the semiconductor device of claim 15, wherein the dielectric layer comprises aluminum oxide (AlO).

17. The method of fabricating the semiconductor device of claim 9, wherein forming the second gate insulating layer on the upper surface of the substrate in the PMOS region comprises
forming a silicon-germanium layer contacting the upper surface of the substrate in the PMOS region, the silicon-germanium layer comprising silicon germanium (SiGe), and
forming the second gate insulating layer on an upper surface of the silicon-germanium layer.

18. A method of fabricating a semiconductor device comprising:
providing a substrate, the substrate comprising an n-channel metal-oxide semiconductor (NMOS) region and a p-channel metal-oxide semiconductor (PMOS) region;
forming a silicon-germanium layer, the silicon-germanium layer contacting an upper surface of the substrate of the PMOS region, the silicon-germanium layer comprising silicon germanium (SiGe);
forming a first gate insulating layer on the upper surface of the substrate in the NMOS region, and forming a second gate insulating layer on an upper surface of the silicon-germanium layer in the PMOS region;
forming a first PMOS conductive layer on an upper surface of the first gate insulating layer and an upper surface of the second gate insulating layer, respectively;
removing the first PMOS conductive layer that is formed on the upper surface of the first gate insulating layer,
forming a protective layer, the protective layer contacting an upper surface of the first PMOS conductive layer, the protective layer comprising Aniline;
forming a first NMOS conductive layer contacting the upper surface of the first gate insulating layer, the first NMOS conductive layer comprising lanthanum oxide (LaO);
removing the protective layer;
forming an oxynitride layer contacting the upper surface of the first PMOS conductive layer, the oxynitride layer comprising titanium oxynitride (TiON); and
forming a second NMOS conductive layer contacting an upper surface of the first NMOS conductive layer, and forming a second PMOS conductive layer contacting an upper surface of the oxynitride layer,
wherein the second NMOS conductive layer, the first PMOS conductive layer, and the second PMOS conductive layer comprises titanium nitride (TiN), and
wherein a thickness of the second PMOS conductive layer in a vertical direction is the same as a thickness of the second NMOS conductive layer in the vertical direction.

19. The method of fabricating the semiconductor device of claim 18, wherein forming the first PMOS conductive layer on the upper surface of the second gate insulating layer comprises
forming a dielectric layer contacting the upper surface of the first gate insulating layer and the upper surface of the second gate insulating layer, the dielectric layer comprising aluminum oxide (AlO),
forming the first PMOS conductive layer contacting an upper surface of the dielectric layer, and
removing the dielectric layer and the first PMOS conductive layer that are formed on the upper surface of the first gate insulating layer.

20. The method of fabricating the semiconductor device of claim 18, wherein the upper surface of the silicon-germanium layer is higher than the upper surface of the substrate in the NMOS region.
